(19) United States
(12) Patent Application Publication
(10) Pub. No.: US 2026/0319357 A1
(43) Pub. Date: Oct. 15, 2026

(54) METHOD FOR REPAIRING LITHOGRAPHY HOTSPOTS OF LAYOUT AND RELATED DEVICES

(71) Applicant: INSTITUTE OF MICROELECTRONICS, CHINESE ACADEMY OF SCIENCES, Beijing (CN)

(72) Inventors: Yajuan Su, Beijing (CN); Zhanzi Chen, Beijing (CN); Yayi Wei, Beijing (CN)

(21) Appl. No.: 19/384,820

(22) Filed: Nov. 10, 2025

(30) Foreign Application Priority Data
Apr. 14, 2025 (CN) 202510462604.6

(51) Int. Cl. G03F 1/72; G06T 7/00; G06T 7/50; G06T 7/73; G06T 11/60

(52) U.S. Cl. CPC G03F 1/72; G06T 7/001; G06T 7/50; G06T 7/74; G06T 11/60; G06T 2207/30148

(57) ABSTRACT

A method and an apparatus for repairing lithography hotspots of a layout are provided. The method includes: acquiring a vector defect layout of an integrated circuit, where the vector defect layout includes mask patterns with lithography hotspots; converting the vector defect layout to a pixel image to obtain a pixel defect layout conforming to a target format; performing sliding window slicing processing on the pixel defect layout to obtain a first slice set; identifying defect slices in the first slice set based on a pre-constructed hotspot geometric template; and performing hotspot repair and conversion on the pixel defect layout based on a hotspot image repair rule and positions of the defect slices in the pixel defect layout, to obtain a vector repaired layout. According to the present disclosure, automated identification and repair of lithography hotspots can be achieved, reducing manual workload and improving repair efficiency and effectiveness.

### CROSS-REFERENCE TO RELATED APPLICATIONS

The present disclosure claims the priority to Chinese Patent Application No. 202510462604.6, titled “METHOD FOR REPAIRING LITHOGRAPHY HOTSPOTS OF LAYOUT AND RELATED DEVICES,” filed on Apr. 14, 2025, with the China National Intellectual Property Administration, the content of which is incorporated herein by reference.

### FIELD

The present disclosure relates to the technical field of integrated circuit manufacturing, and specifically relates to a method for repairing lithography hotspots of a layout and related devices.

### BACKGROUND

In mask patterns of an integrated circuit, the sizes of graphics of critical layers are often smaller than a wavelength of a light source of a lithography machine, causing the lithography machine to fail to achieve ideal imaging of the mask patterns, and thereby leading to an optical proximity effect (OPE). The OPE leads to distortions of the graphics on a silicon wafer after exposure, such as a rounded edge or corner, a biased line width, a shortened line end, and partial regions missed in a pattern, which may further result in defects such as bridging or broken lines. The layout regions that may lead to wafer defects are referred to as lithography hotspots. The lithography hotspots may cause problems like short circuit, open circuit, and poor contact in the circuit, severely affecting an electrical characteristic and a manufacturing yield of the integrated circuit. Conventional repair methods rely on manual experience and usually require manual repair, which is time-consuming and has a poor convergence effect.

Therefore, how to effectively and quickly repair the lithography hotspots due to the OPE while avoiding the inefficiency and instability of conventional manual repair methods is a technical issue urgently to be addressed by those skilled in the art.

### SUMMARY

Based on the above issues, a method and an apparatus for repairing lithography hotspots of a layout are provided according to the present disclosure, which can effectively and quickly repair the lithography hotspots due to an optical proximity effect (OPE) while avoiding the inefficiency and instability of conventional manual repair methods.

Technical solutions are provided as follows according to embodiments of the present disclosure.

A method for repairing lithography hotspots of a layout is provided according to an embodiment of the present disclosure, including:
acquiring a vector defect layout of an integrated circuit, where the vector defect layout includes N mask patterns with lithography hotspots and M mask patterns without lithography hotspots, and N is a positive integer and M is a non-negative integer;
converting the vector defect layout to a pixel image to obtain a pixel defect layout conforming to a target format;
performing sliding window slicing processing on the pixel defect layout to obtain a first slice set, where the first slice set includes multiple layout slices;
identifying defect slices in the first slice set based on a pre-constructed hotspot geometric template; and
performing hotspot repair and conversion on the pixel defect layout based on a hotspot image repair rule and positions of the defect slices in the pixel defect layout, to obtain a vector repaired layout.

In an embodiment, the converting the vector defect layout to a pixel image to obtain a pixel defect layout conforming to a target format includes:
identifying shapes and vertex coordinates of polygons in the vector defect layout;
performing, based on the shapes and the vertex coordinates of the polygons in the vector defect layout, edge-based Hanan gridding on the vector defect layout to obtain a gridded layout, where the gridded layout includes multiple grids;
mapping the gridded layout to a pixel space to obtain a Boolean matrix, and recording horizontal spacings and vertical spacings between adjacent grids in the gridded layout;
converting the vector defect layout to an initial pixel layout based on the Boolean matrix in conjunction with the horizontal spacings and the vertical spacings between adjacent grids in the gridded layout; and
converting a format of the initial pixel layout to the target format to obtain the pixel defect layout.

In an embodiment, the performing sliding window slicing processing on the pixel defect layout to obtain a first slice set includes:
defining a slicing window; and
the slicing window starting from a top left corner of the pixel defect layout and sliding successively from left to right and from top to bottom on the pixel defect layout by a predetermined step size until the pixel defect layout is entirely scanned, to obtain the first slice set,
where a region covered by the slicing window during each scanning is a layout slice, and all layout slices compose the first slice set.

In an embodiment, the performing hotspot repair and conversion on the pixel defect layout based on a hotspot image repair rule and positions of the defect slices in the pixel defect layout, to obtain a vector repaired layout includes:
performing hotspot repair on the defect slices based on the hotspot image repair rule to obtain multiple repaired slices;
replacing, in the pixel defect layout, images at the positions of the defect slices one by one with their respective repaired slices in the multiple repaired slices, to obtain a pixel repaired layout; and vectorizing the pixel repaired layout to obtain the vector repaired layout.

In an embodiment, the hotspot geometric template is constructed by:
selecting X sample layouts, where each of the sample layouts includes multiple pixel-level mask patterns with lithography hotspots concentrated in a central region of the sample layout, and X is a positive integer;
for each of the sample layouts, performing sliding window slicing processing to obtain a second slice set corresponding to the sample layout, where the second slice set includes multiple sample slices;
for each of the sample layouts, selecting Y sample slices located around the central region of the sample layout to obtain Y target slices, where Y is a positive integer; and
merging and clustering XXY target slices to obtain the hotspot geometric template.

In an embodiment, the hotspot image repair rule includes a graphic movement rule and a graphic-edge shrinkage rule.

In an embodiment, before the vectorizing the pixel repaired layout to obtain the vector repaired layout, the method further includes:
performing evaluation of a process window value on the pixel repaired layout, and performing the process of vectorizing the pixel repaired layout to obtain the vector repaired layout in response to the evaluation passing.

An apparatus for repairing lithography hotspots of a layout is provided according to an embodiment of the present disclosure. The apparatus includes an acquisition unit, a first image conversion unit, a first slicing unit, a defect identification unit, and a first repair unit.

The acquisition unit is configured to acquire a vector defect layout of an integrated circuit, where the vector defect layout includes mask patterns with lithography hotspots.

The first image conversion unit is configured to convert the vector defect layout to a pixel image to obtain a pixel defect layout conforming to a target format.

The first slicing unit is configured to perform sliding window slicing processing on the pixel defect layout to obtain a first slice set, where the first slice set includes multiple layout slices.

The defect identification unit is configured to identify defect slices in the first slice set based on a pre-constructed hotspot geometric template.

The first repair unit is configured to perform hotspot repair and conversion on the pixel defect layout based on a hotspot image repair rule and positions of the defect slices in the pixel defect layout, to obtain a vector repaired layout.

A device for repairing lithography hotspots of a layout is provided according to an embodiment of the present disclosure. The device includes: a memory, a processor, and a computer program stored on the memory and executable on the processor, where the processor, when executing the computer program, implements the method for repairing the lithography hotspots of the layout as described above.

A computer-readable storage medium is provided according to an embodiment of the present disclosure. The computer-readable storage medium stores instructions. The instructions, when executed on a terminal device, cause the terminal device to perform the method for repairing the lithography hotspots of the layout as described above.

### BRIEF DESCRIPTION OF THE DRAWINGS

For more clearly illustrating the technical solutions in embodiments and conventional technology, drawings referred to describe the embodiments or the conventional technology will be briefly described hereinafter. Apparently, the drawings in the following description are only some embodiments of the present disclosure, and for those skilled in the art, other drawings may be obtained based on these drawings without any creative efforts.

FIG. 1 is a flowchart of a method for repairing lithography hotspots of a layout according to an embodiment of the present disclosure;

FIG. 2 shows a PNG-format pixel defect layout according to an embodiment of the present disclosure;

FIG. 3 shows a layout slice according to an embodiment of the present disclosure;

FIG. 4 shows a hotspot geometric template according to an embodiment of the present disclosure;

FIG. 5 is a flowchart of a method for converting a vector defect layout to a pixel defect layout according to an embodiment of the present disclosure;

FIG. 6 is a schematic diagram of a Hanan grid pixelating process according to an embodiment of the present disclosure;

FIG. 7 shows a Boolean matrix according to an embodiment of the present disclosure;

FIG. 8 is a flowchart of a method for repairing lithography hotspots of a layout according to another embodiment of the present disclosure;

FIG. 9 is a schematic diagram of a correction target according to an embodiment of the present disclosure;

FIG. 10 is a flowchart of a method for constructing a hotspot geometric template according to an embodiment of the present disclosure; and

FIG. 11 is a schematic structural diagram of an apparatus for repairing lithography hotspots of a layout according to an embodiment of the present disclosure.

### DETAILED DESCRIPTION

In order to facilitate understanding of the technical solutions provided in the embodiments of the present disclosure, the background involved in the embodiments of the present disclosure is first illustrated below.

“Poor convergence effect” refers to the ineffectiveness or difficulty in rapidly achieving the desired repair objectives when conventional repair methods are applied to address lithography hotspot issues.

In a manufacturing process for an integrated circuit, the sizes of critical graphics in designed mask patterns are smaller than a wavelength of a light source used by a lithography machine. The lithography machine is configured to illuminate a mask with the light source and project a pattern onto a silicon wafer through an optical system, to form a circuit pattern. However, the wavelength of the light source of the lithography machine is typically in an ultraviolet light range, on the order of several tens to hundreds of nanometers (for example, a deep ultraviolet light of 193 nanometers). Imaging difficulties arise when the sizes of the critical graphics (such as thin lines, holes, or other fine structures) in the mask patterns are smaller than the wavelength of the light source. Since the wavelength of the light source limits its resolution, it becomes impossible to accurately transfer these tiny graphics onto the silicon wafer integrally, resulting in an optical proximity effect (OPE) and causing distortions of the patterns.

At present, repairing lithography hotspots usually relies on manual repairs by manufacturing engineers, which is highly time-consuming and has a poor convergence effect. Also, as semiconductor technology nodes advance and design rules increase exponentially, the number of lithography hotspots generated in the mask patterns becomes increasingly greater, further slowing down the speed of manual repairs.

In order to address this issue, a method for repairing lithography hotspots of a layout and related devices are provided according to embodiments of the present disclosure. A vector defect layout with lithography hotspots is first acquired and the vector defect layout is converted to a pixel defect layout conforming to a target format. Next, sliding window slicing processing is performed to obtain multiple layout slices. Defect slices are identified by using a pre-constructed hotspot geometric template, and the pixel defect layout is repaired and converted based on a hotspot repair rule and position information of the defect slices, thereby obtaining a vector repaired layout. According to the present disclosure, by converting the vector defect layout to the pixel image, the sliding window slicing processing is performed on the pixel defect layout and the defect slices are automatically identified by using the hotspot geometric template, which avoids the inefficiency and instability of the conventional manual repair methods. Further, automatic repair is performed based on the pre-constructed hotspot geometric template and the hotspot image repair rule, which can more accurately repair the lithography hotspots and reduce repair errors compared with the manual methods.

The technical solutions in the embodiments of the present disclosure are described clearly and completely in conjunction with the drawings in the embodiments of the present disclosure hereinafter. It is apparent that the described embodiments are only some rather than all embodiments of the present disclosure. All the other embodiments obtained by those skilled in the art based on the embodiments of the present disclosure without any creative work belong to the protection scope of the present disclosure.

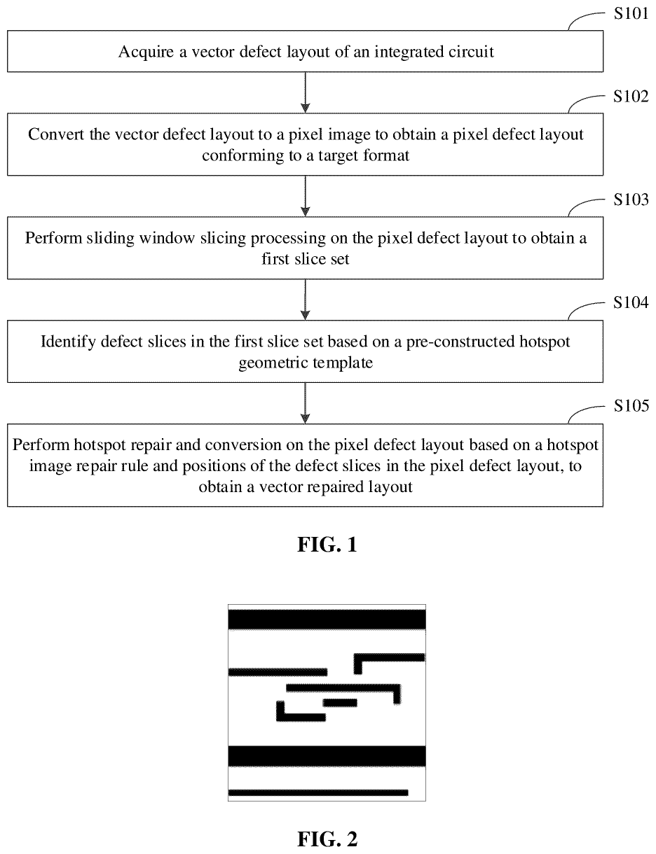

Reference is made to FIG. 1, which is a flowchart of a method for repairing lithography hotspots of a layout according to an embodiment of the present disclosure. As shown in FIG. 1, the method for repairing the lithography hotspots of the layout includes steps S101 to S105.

In step S101, a vector defect layout of an integrated circuit is acquired.

In the method, the “vector defect layout” of the integrated circuit is first acquired. This layout includes N mask patterns with lithography hotspots and M mask patterns without lithography hotspots. That is, the vector defect layout must include mask patterns with lithography hotspots, but does not necessarily include mask patterns without lithography hotspots.

The vector defect layout is an integrated circuit layout described by using vector data, which can accurately represent information such as shapes, sizes, and positions of the mask patterns in the integrated circuit. During the lithography process, some defects, called “lithography hotspots”, may appear, and these defects may affect the performance or yield of a circuit.

The mask patterns with lithography hotspots are prone to defects during the lithography process, typically due to unreasonable layout design or problems in the lithography process. These defects may cause the circuit to fail to work properly, or even lead to functional damage to the circuit.

The mask patterns without lithography hotspots exhibit no defects during the lithography process and are normal sections that do not require repair.

The step S101 is the foundation of the entire repair method. Only by accurately acquiring a design layout with lithography hotspots can subsequent identification and repair operations be further performed. By acquiring the vector defect layout, it is ensured that subsequent processing steps can accurately identify and repair the actual problems, thereby improving the design quality and manufacturing success rate of the integrated circuit.

In a possible implementation, an image format of the vector defect layout is graphic data system II (GDSII). GDSII is a standard format for describing integrated circuit layout data. A GDSII file is a binary file format for storing and transmitting geometry information, hierarchical structures, and related attribute information of an integrated circuit layout.

In step S102, the vector defect layout is converted to a pixel image to obtain a pixel defect layout conforming to a target format.

After the vector defect layout is obtained, the vector defect layout of the integrated circuit is converted to the pixel image, and thus the pixel defect layout conforming to the target format is obtained. Here, the “vector defect layout” refers to the mask patterns with lithography hotspots, and the “pixel image” refers to an image composed of pixels which is converted from vector data.

The purpose of this step is to facilitate subsequent processing and analysis. Although the vector data is precise, pixel images are more advantageous when applying large-scale image processing and machine learning models. By converting the vector defect layout to the pixel image, operations such as sliding window slicing processing and defect identification are performed more easily. In addition, many conventional image processing technologies and algorithms are more suitable for processing pixelated image data. Therefore, in this step necessary data format preparations are made for subsequent defect identification and repair processes.

In a possible implementation, the target format may be, but is not limited to, a portable network graphics (PNG) format. As shown in FIG. 2, FIG. 2 shows a PNG-format pixel defect layout according to an embodiment of the present disclosure.

In step S103, sliding window slicing processing is performed on the pixel defect layout to obtain a first slice set.

In this step, the sliding window slicing processing is performed on the previously obtained pixel defect layout to obtain the first slice set. Specifically, the sliding window slicing processing refers to using a fixed-size window to slide across the pixel defect layout at a certain step size, thereby cutting out multiple small layout slices from the layout. These slices compose the first slice set.

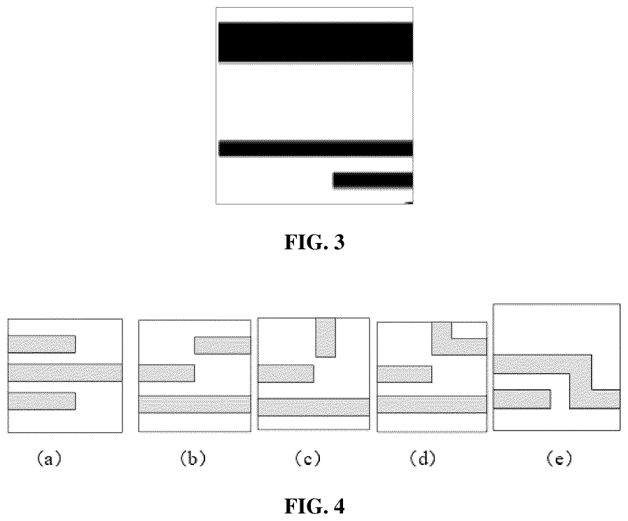

The purpose of this step is to partition the entire pixel defect layout into multiple smaller, easily processed layout slices for subsequent finer analysis and processing. In this way, the accuracy and efficiency of defect identification may be effectively improved. Hotspot geometric template matching and defect identification may be independently performed on each of the slices, which not only reduces the consumption of computational resources, but also improves detection precision and avoids omissions or misjudgments. As shown in FIG. 3, FIG. 3 shows a layout slice according to an embodiment of the present disclosure.

In step S104, defect slices in the first slice set are identified based on a pre-constructed hotspot geometric template.

After the slice set (that is, the first slice set) of the pixel defect layout is obtained, layout slices with defects in the slice set are identified based on the pre-constructed hotspot geometric template, and are defined as the defect slices. This process involves matching the pre-constructed hotspot geometric template (typically representing known hotspot patterns or features) against the multiple layout slices extracted from the pixel defect layout. Through this matching, those slices that match the hotspot geometric template are identified, that is, the defect slices with lithography hotspots are found. As shown in FIG. 4, FIG. 4 shows a hotspot geometric template according to an embodiment of the present disclosure, and the template includes five subtemplates (a), (b), (c), (d), and (e).

Specifically, the hotspot geometric template is compared with the layout slices by using a template matching method. When a similarity between a hotspot geometric template and a layout slice is high, it is considered that the layout slice contains a hotspot region. In the present disclosure, a normalized cross-correlation (NCC) matching metric method is used to evaluate the similarity between the layout slice and the hotspot geometric template, and an equation for calculating NCC is expressed as follows.

$$NCC = \frac{{\sum }_{i = 1}^{N} ( I ( i ) - \overline{I} ) ( T ( i ) - \overline{T} )}{\sqrt{{\sum }_{i = 1}^{N} {( I ( i ) - \overline{I} )}^{2} {\sum }_{i = 1}^{N} {( T ( i ) - \overline{T} )}^{2}}}$$

In the equation, NCC presents the similarity, I(i) and T(i) represent i-th pixel values of the layout slice and the hotspot geometric template, respectively, Ī and T̅ represent average pixel values of the layout slice and the hotspot geometric template, respectively, and N represents a total number of pixels in the template. With the equation, the NCC coefficient between the hotspot geometric template and the layout slice is calculated. A larger NCC value indicates a higher similarity. Then a matching metric value between the layout slice and the hotspot geometric template is calculated according to the equation. A threshold is set, and when the matching metric value is higher than the threshold, it is considered that the layout slice has extremely high similarity with the hotspot geometric template, that is, the layout slice contains the hotspot region. Finally, layout slices containing hotspot regions are determined as input data for a next repair stage (that is, the defect slices in the first slice set are identified).

The purpose of this step is to accurately locate and identify the defect slices with lithography hotspots. By using the hotspot geometric template for matching, potential problem regions are efficiently and accurately identified, which provides a clear target for subsequent repair work. The slices conforming to a specific pattern are quickly identified through a template matching algorithm, thereby improving the accuracy of defect identification and reducing the processing time.

In step S105, hotspot repair and conversion are performed on the pixel defect layout based on a hotspot image repair rule and positions of the defect slices in the pixel defect layout, to obtain a vector repaired layout.

Based on the predefined hotspot image repair rule and the identified positions of the defect slices in the pixel defect layout, hotspot repair is performed on the original pixel defect layout, and then vector conversion is performed on the repaired pixel defect layout, so as to generate the vector repaired layout. Specifically, this step involves the following.

The hotspot image repair rule defines how to process and correct detected lithography hotspots. These rules may include specific algorithms or methods for eliminating or mitigating hotspots in the layout.

The defect slices with lithography hotspots and the positions of the defect slices in the pixel defect layout are identified in step S104. The position information is crucial to accurately locate the regions that needs to be repaired.

Repair of the pixel defect layout includes: repairing the original pixel defect layout based on the above repair rule and position information to eliminate the lithography hotspots, and performing vector conversion on the repaired pixel defect layout to generate the vector repaired layout. The generated vector repaired layout is an optimized layout that eliminates the original hotspots.

The purpose of this step is to practically repair the lithography hotspots in the layout, ensuring that for a final layout, defects or errors caused by lithography hotspots are avoided in a manufacturing process. Through this repair process, the quality of the layout is improved, and the manufacturing success rate and reliability of the integrated circuit are enhanced.

Based on the contents in steps S101 to S105, the vector defect layout with lithography hotspots in the integrated circuit is first acquired and the vector defect layout is converted to the pixel defect layout conforming to the target format. Then, sliding window slicing processing is performed to partition the pixel defect layout into multiple layout slices. The layout slices containing defects are identified by means of the pre-constructed hotspot geometric template. Finally, based on the hotspot repair rule and the positions of the defect slices, repair and conversion are performed on the pixel defect layout to generate the vector repaired layout. In the present disclosure, the vector defect layout is converted to the pixel image through an automatic process for accurately identifying and repairing lithography hotspots, thereby improving repair efficiency and accuracy. The pre-constructed hotspot geometric template and the repair rule are employed to quickly detect the defect slices and accurately locate and repair the lithography hotspots.

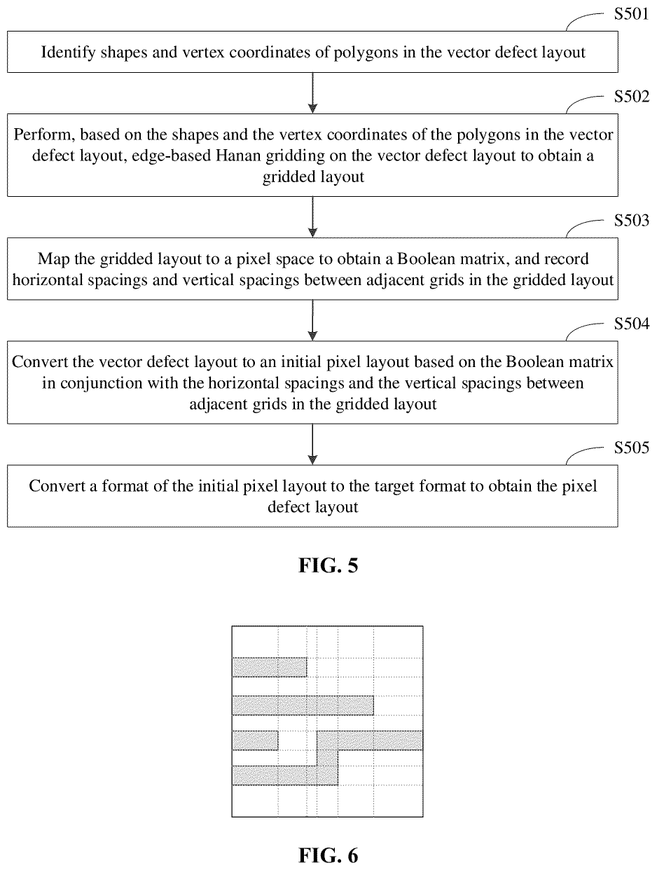

Reference is made to FIG. 5, which is a flowchart of a method for converting a vector defect layout to a pixel defect layout according to an embodiment of the present disclosure. Accordingly, in step S102, the converting the vector defect layout to the pixel image to obtain the pixel defect layout conforming to the target format includes the following steps S501 to S505.

In step S501, shapes and vertex coordinates of polygons in the vector defect layout are identified.

In order to implement conversion of the vector defect layout to the pixel defect layout, the shapes and the vertex coordinates of the polygons are first extracted from the vector defect layout. These polygons typically represent regions of the integrated circuit layout and may include circuit elements. The shapes and the vertex coordinates of the polygons are identified for a subsequent gridding process.

In a possible implementation, identifying the shapes and the vertex coordinates of the polygons in the vector defect layout includes:
extracting geometric data in the vector defect layout by using the Klayout library in Python, where the geometric data includes the shapes and the vertex coordinates of the polygons in the vector defect layout.

It should be noted that the shapes of the polygons in the vector defect layout are generally regular rectangles.

In step S502, based on the shapes and the vertex coordinates of the polygons in the vector defect layout, edge-based Hanan gridding is performed on the vector defect layout to obtain a gridded layout.

Hanan gridding is a method for converting a vector layout into a gridded layout. In the step, based on the shapes and the vertex coordinates of the polygons, the vector layout is converted into the gridded layout. Specifically, the geometric shapes of the vector defect layout are mapped onto a regular grid structure by gridding, and edge-based processing allows the gridded layout more accurate and standardized. The generated gridded layout includes multiple grids, and these grids may accurately represent the vector defect layout.

In the present disclosure, a Hanan grid is introduced to replace a uniformly distributed grid. The structure of the Hanan grid is relatively flexible and can be dynamically adjusted according to characteristics of the graphics and layout constraints. A pixel size is set smaller in regions with complex graphics including multiple corners and dense lines, and a pixel size is set larger in regions with uniform graphics and simple structures. The specific process of Hanan gridding is described as follows. As shown in FIG. 6, the gray graphic represents a graphic in the vector defect layout, where the gray graphic includes multiple polygons and the multiple polygons form multiple edges. By extending these edges, the black dotted-line grids shown in FIG. 6 are obtained. These extension lines divide the vector defect layout into multiple rectangular regions (i.e., grids), with each region representing a pixel.

In step S503, the gridded layout is mapped to a pixel space to obtain a Boolean matrix, and horizontal spacings and vertical spacings between adjacent grids in the gridded layout are recorded.

After the gridded layout is obtained, the gridded layout is mapped to the pixel space and converted into the Boolean matrix. Each element of the Boolean matrix corresponds to a pixel, and the value of the element indicates whether the pixel belongs to a defect region. In this way, original vector-based data is converted into a pixel-based representation. In addition, the horizontal spacings and vertical spacings are recorded, which helps to preserve a spatial relationship of the original layout when reconstructing the layout in the pixel space in the following steps.

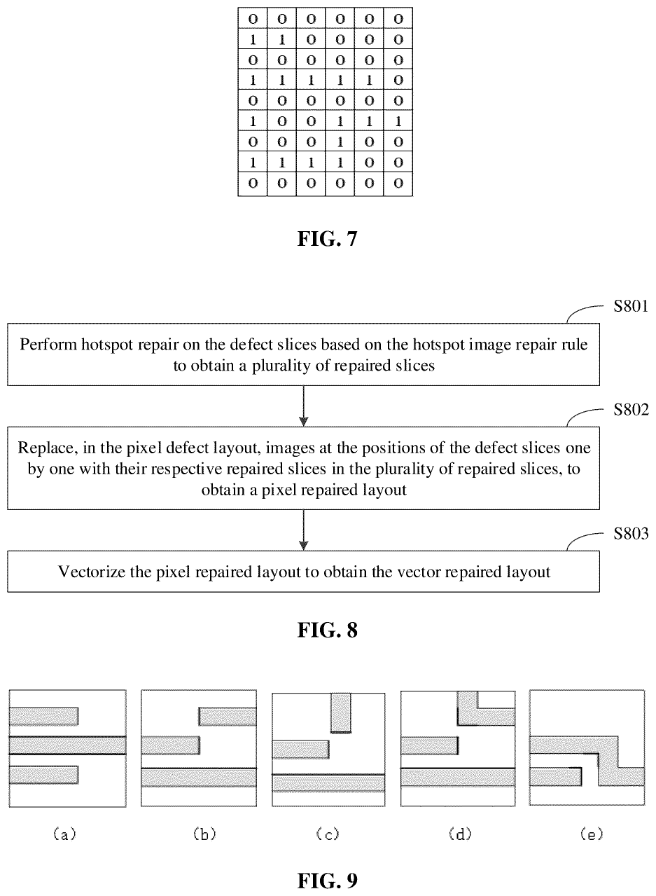

Specifically, for the rectangular regions in FIG. 6, a pixel corresponding to a rectangular region is encoded as 1 in a case that the rectangular region contains a lithography hotspot, and a pixel corresponding to a rectangular region is encoded as 0 in a case that the rectangular region contains no lithography hotspot. In this way, the Boolean matrix shown in FIG. 7 is obtained. Furthermore, the horizontal spacings and vertical spacings between adjacent grids are recorded. Based on the spacing information between the Hanan grids and the Boolean matrix, all graphic information and relative position relationships in the vector defect layout are represented in detail and accurately.

In step S504, based on the Boolean matrix in conjunction with the horizontal spacings and the vertical spacings between adjacent grids in the gridded layout, the vector defect layout is converted to an initial pixel layout.

After the Boolean matrix is obtained, in conjunction with the Boolean matrix and the spacing information in the gridded layout, the vector defect layout is converted to the initial pixel layout. The Boolean matrix provides basic pixel information about the defect region, while the recording horizontal spacings and vertical spacings ensures that spatial relationships are preserved when reconstructing the layout in the pixel space.

In a possible implementation, the converting the vector defect layout to an initial pixel layout based on the Boolean matrix in conjunction with the horizontal spacings and the vertical spacings between adjacent grids in the gridded layout includes:
creating an image canvas determined based on a size of the layout and a required resolution, and drawing geometric shapes on the Hanan grid by using a PIL library based on the Boolean matrix in conjunction with the horizontal spacings and the vertical spacings between adjacent grids in the gridded layout to accurately map the vector defect layout to the pixel space.

In step S505, a format of the initial pixel layout is converted to the target format to obtain the pixel defect layout.

The purpose of converting the format of the obtained initial pixel layout to the target format is to ensure that the generated pixel defect layout meets specific output requirements, which may include file format, resolution, or other specific format standards, ultimately generating the pixel defect layout that conforms to the target format.

Specifically, the drawn layout (that is, the initial pixel layout) is saved as an image file in the target format (for example, a PNG format) to ensure the integrity of graphical details and provide a foundation for a subsequent hotspot repair operation. As shown in FIG. 2, the vector layout is converted to a pixel image with a 120×120 resolution, effectively achieving the conversion of the vector defect layout from a GDSII format to a PNG format.

In a possible implementation, the performing sliding window slicing processing on the pixel defect layout to obtain a first slice set includes the following steps A1 to A2.

In step A1, a slicing window is defined. A size and a shape of the slicing window are defined. The slicing window covers a part of the pixel defect layout in a subsequent scanning process.

In step A2, the slicing window slides. Starting from a top left corner of the pixel defect layout, the slicing window slides across the pixel defect layout by a predetermined step size. The sequence of the sliding process is as follows: the slicing window slides from left to right until reaching a right edge of the pixel defect layout, and then moves downward row by row until the pixel defect layout is entirely scanned.

A region covered by the slicing window during each scanning is regarded as a layout slice. Each slice is a small region that represents a part of the pixel defect layout.

It should be noted that all the layout slices are acquired successively through the scanning process and eventually compose the first slice set. The first slice set includes multiple small parts of the entire pixel defect layout, and each layout slice contains information of different regions.

In a possible implementation, a size of the pixel defect layout in the present disclosure is 1.2×1.2 square micrometers (μm²), and therefore a size of the slicing window is set to 400×400 square nanometers (nm²) and the predetermined step size is set to 200 nanometers (nm).

Specifically, the size of the pixel defect layout in the present disclosure is 1.2×1.2 μm², and to ensure that the layout slices contain critical features of the graphics as much as possible while reducing the workload of the subsequent processing, the size of the slicing window is set to 400×400 nm² in the present disclosure. Regarding the determination of the predetermined step size, in a case that the predetermined step size is the same as the size of the slicing window, a graphic located at a boundary of two adjacent windows is split into different layout slices, which causes the loss of some critical graphical structures and affects the subsequent repair operation. In order to avoid the situation, the step size is generally smaller than the size of the slicing window. However, a smaller step size may lead to an excessive number of generated layout slices, thereby resulting in a large amount of redundant information and bringing more processing and computation pressure to the subsequent steps. Therefore, the step size is set to 200 nm in the present disclosure. The above settings are applied to an image format, the resolution of the pixel defect layout is 120×120 pixels, the size of the slicing window is 40×40 pixels, and the predetermined step size is 20 pixels. Based on the parameter settings, 25 layout slices may be obtained from each layout sample. Slicing processing is performed on the layout sample illustrated in FIG. 2 according to the sliding window method described above, and one of the layout slices is shown in FIG. 3.

Through this process, the large pixel defect layout is divided into multiple small layout slices by using the slicing window, facilitating subsequent processing such as defect identification or repair.

Reference is made to FIG. 8, which is a flowchart of a method for repairing lithography hotspots of a layout according to another embodiment of the present disclosure. Accordingly, the performing hotspot repair and conversion on the pixel defect layout based on a hotspot image repair rule and positions of the defect slices in the pixel defect layout, to obtain a vector repaired layout in step S105 includes the following steps S801 to S803.

In step S801, hotspot repair is performed on the defect slices based on the hotspot image repair rule to obtain multiple repaired slices.

In step S801, the repair rule is first applied to the defect slices, and each defect slice after repair is referred to as a repaired slice.

In a possible implementation, image preprocessing, contour detection, and feature size calculation are required for the defect slices before performing hotspot repair on the defect slices.

Specifically, to perform hotspot repair on the defect slices containing hotspot regions, information such as boundary coordinates and feature sizes of the defect slices is first extracted, which requires applying the knowledge in the field of image processing. Specifically, the process of extracting the information includes two main stages: image preprocessing and contour detection. The image preprocessing is a foundation of the entire repair operation, and includes converting an original color image into a grayscale image and binarization processing. The color image contains multiple channels, while the grayscale image contains only a single luminance channel. The conversion may be implemented by using the cvtColor( ) function in the open source computer vision library (OpenCV). Grayscaling simplifies the complexity of the image, making subsequent processing more efficient. The binarization processing includes converting the grayscale image into a binary image with only black and white colors by using the threshold( ) function, highlighting a difference between a graphic and a background, making a graphic contour clearer, and laying a foundation for the subsequent contour detection.

After the image preprocessing, the contour detection is performed to identify all closed boundaries in the defect slices and extract coordinate points of these boundaries. In OpenCV, the findContours( ) function is the core tool to achieve the contour detection. The function detects and extracts all contours in the image by scanning the binary image based on connectivity of pixels. Each contour consists of a series of continuous coordinate points, and these points represent boundary information of the graphic. The findContours( ) function returns a list of contours, where each contour is represented by an array containing the coordinate points of pixels. Through this process, graphic boundary information in the defect slices is extracted, and the information is crucial for subsequent analysis and repair and determines the accuracy of the repair operation.

After completing the contour detection and extracting the boundary coordinate information of the defect slices, the feature sizes of graphics in the defect slices are calculated based on the above information. For different types of graphics, the calculation methods for the feature sizes are different. The detected contours are classified by analyzing geometric features and topological features of the contours. For example, by calculating features such as the number of endpoints, a side length, a bounding rectangle, a length-width ratio, and a minimum circumcircle for each contour, a line graphic with a high length-width ratio, an independent square with a length-width ratio close to 1, and a corner graphic with a distinct corner point are identified. Line endpoints and T-shaped structures are determined by analyzing the number of endpoints and a branch structure of the contours. Based on these classification results, the feature sizes of the graphics are further calculated, serving as a basis for the subsequent repair operation.

In step S802, in the pixel defect layout, images at the positions of the defect slices are replaced one by one with their respective repaired slices in the multiple repaired slices, to obtain a pixel repaired layout.

In step S802, the repaired defect slices are applied to their corresponding positions in the original pixel defect layout. Specifically, the originally defective image regions are replaced with the repaired slices of the defect slices.

This process is performed at a pixel level. The defect slices in the pixel defect layout are replaced one by one with the repaired slices, ensuring that each defect slice is properly repaired and adjusted. The result after replacement is a new pixel repaired layout, which repairs the original defects and exactly matches the repaired slices at the pixel level.

In step S803, the pixel repaired layout is vectorized to obtain the vector repaired layout.

In step S803, the pixel repaired layout is converted back into a vector form. Vectorization is the reconversion of pixel-based image data into a geometry-based representation, which is particularly important for the integrated circuit layout, as vector data can accurately describe circuit structures and connecting lines.

In this process, the pixel repaired layout is analyzed and converted into vector data, ultimately generating the vector repaired layout. This vector repaired layout includes repaired defect regions and conforms to format requirements of a vector layout, making it suitable for subsequent production or design verification.

In a possible implementation, the hotspot image repair rule includes: a graphic movement rule and a graphic-edge shrinkage rule.

Specifically, the graphic movement rule increases a spacing between graphics by translating the graphics as a whole. The specific process includes: identifying a graphic to be moved, and translating the graphic by a certain step size in a specified direction, to ensure that the spacing is increased without changing the size of the graphic. The graphic-edge shrinkage rule precisely controls a local spacing by adjusting a certain edge of a graphic. The specific process includes: identifying a graphic edge to be adjusted, and shrinking the edge in a desired direction to increase the spacing, being particularly suitable for local optimization, enabling hotspots to be repaired without affecting other regions, and reducing generation of new hotspots.

In a possible implementation, a shrink_pattern (contour, side, step) function is defined for shrinking the graphic edge (or moving the graphic) by a fixed step size. Here, “contour” represents a contour to be processed, which is an array containing two-dimensional pixel coordinate points, “side” represents the edge to be shrunk, and “step” represents a step size for shrinkage, that is, a distance the edge is moved in a specified direction. For the function, coordinates of the contour are first acquired; the coordinates of the contour are adjusted by using a np.clip( ) function to move edges of the graphic by the fixed step size and ensure that the adjusted coordinates do not exceed a range of an initial contour; a specified edge (top, bottom, left, or right) is determined for moving according to an inputted “side” parameter; and the modified contour is outputted as a return value of the function.

How to reasonably determine parameters of the above function is key to the repair operation. For the five geometric subtemplates containing hotspot regions described above (shown in FIG. 4), to-be-repaired graphics and to-be-moved edges are determined, that is, the repair rule for the geometric subtemplates are determined. As shown in FIG. 9, the black bold solid lines represent targets to be corrected. According to the repair rule, for hotspot regions belonging to different subtemplates, to-be-repaired contours and to-be-moved edges of the contours are determined as the “contour” and “side” parameters of the shrink_pattern( ) function.

How to determine an appropriate “step” is described as follows. In the above function, setting of the “step” has an important effect on a process window and repair time. A larger “step” can increase repair speed and reduce repair time, as the magnitude of each adjustment is larger and the number of iterations required is reduced. However, this may lead to over-adjustment or low accuracy, resulting in a poorer process window for the repaired layout. On the contrary, a smaller “step”, though increasing the repair time, allows for finer correction, resulting in a better process window for the repaired layout. Therefore, for the “step”, a balance between the repair time and good quality is required for an efficient layout repair. In view of this, the “step” of the function is set to 2 when applying the repair rule for (a) to (d) in FIG. 4; while the “step” is set to 1 when applying the repair rule for (e) in FIG. 4. It should be noted that 2 and 1 here refer to image pixels, which correspond to 0.02 μm and 0.01 μm, respectively, when converted to the GDSII format.

In a possible implementation, before the vectorizing the pixel repaired layout to obtain the vector repaired layout in step S803, the method further includes steps B1 to B2:

In step B1, evaluation of a process window value is performed. Before the vectorization, the evaluation of the process window value is performed on the pixel repaired layout, to check whether the pixel repaired layout meets a certain process requirement or standard. If the evaluation of the process window value passes, that is, the pixel repaired layout meets a predetermined requirement, the vectorization is performed.

In step B2, the vectorization is performed. Once the evaluation passes, the process of vectorizing the pixel repaired layout is performed to obtain the vector repaired layout.

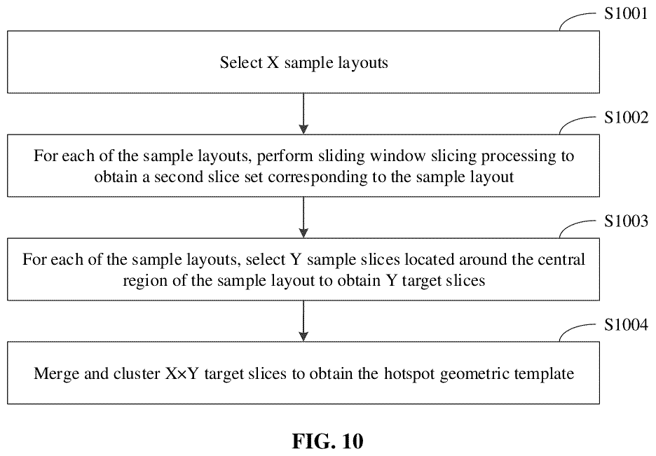

Reference is made to FIG. 10, which is a flowchart of a method for constructing a hotspot geometric template according to an embodiment of the present disclosure, and the method includes the following steps S1001 to S1004.

In step S1001, X sample layouts are selected.

In step S1001, X sample layouts are selected, and each of the sample layouts includes multiple pixel-level mask patterns with lithography hotspots concentrated in a central region of the sample layout.

The sample layouts refer to those layouts in which hotspots (that is, regions prone to failures or performance problems) appear in central regions of the layouts due to different parameters or defects in the lithography process during the production process. These sample layouts are used for simulating and analyzing distribution characteristics of hotspots.

X is a positive integer, which means that multiple sample layouts are selected to improve the reliability and adaptability of data.

In step S1002, for each of the sample layouts, sliding window slicing processing is performed to obtain a second slice set corresponding to the sample layout.

In step S1002, the sliding window slicing processing is performed on each of the sample layouts. The sliding window slicing processing involves applying a sliding window algorithm to the sample layout, to partition the sample layout into multiple small regions, that is, slices, at a certain size and step size.

The second slice set is a set of multiple sample slices obtained by the sliding window slicing processing. Each sample slice is a small region of the sample layout, and contains hotspot information around the central region.

The purpose of this process is to extract smaller slices from each of the sample layouts for subsequent analysis and processing.

It should be noted that the sliding window slicing processing in step S1002 is similar to the sliding window slicing processing in step S103, which is not repeated herein.

In step S1003, for each of the sample layouts, Y sample slices located around the central region of the sample layout are selected to obtain Y target slices.

In step S1003, for each of the sample layouts, Y sample slices located around the center region of the sample layout are selected from the obtained second slice set.

Y is a positive integer, indicating that multiple sample slices selected around the center region are the slices that best represent the hotspot regions. By selecting these slices, geometric features of the hotspots are effectively captured.

These target slices are used for further template construction and analysis.

In step S1004, XxY target slices are merged and clustered to obtain the hotspot geometric template.

In step S1004, all target slices obtained in step S1003 are merged and clustered.

The process of merging and clustering involves extracting common features from different slices to obtain the hotspot geometric template (as shown in FIG. 4, the hotspot geometric template includes 5 subtemplates (a), (b), (c), (d) and (e)). The hotspot geometric template can characterize the common hotspot geometric features around the central region, and is used for subsequent repair.

The hotspot geometric template is conducive to identifying potential hotspot regions, thereby performing the repair operation.

In an embodiment of the present disclosure, cluster analysis is performed on the sample layouts containing hotspots, to obtain the hotspot geometric template that characterizes design rules of the hotspot regions. For each of the sample layouts containing hotspots, the hotspots are located in the central region of the sample layout. To reduce computational burden of subsequent cluster analysis, Y sample slices (for example, 12 sample slices) located around the central region of the sample layout are selected from the sample slices (for example, 25 sample slices) of the layout sample, to obtain XxY target slices (if X is 100, XxY=1200). The cluster analysis is performed to gradually merge the closest slices among the 1200 target slices until no further merging is possible, thereby dividing the target slices containing hotspots into five clusters.

After the cluster analysis is performed on the target slices, a set of geometric rules is summarized from each cluster to represent geometric features of hotspot regions of all slices within the cluster. The geometric rules include basic graphic structures (such as line endpoints, corners, and dense lines) in the layout or a combination of some graphic structures. For each cluster, a corresponding set of geometric rules, that is, geometric templates, is extracted. The five geometric templates used in the present disclosure are eventually obtained, as shown in FIG. 4.

In a possible implementation, an agglomerative nesting (AGNES) algorithm is used for the cluster analysis of the target slices. The AGNES algorithm is a typical hierarchical clustering algorithm. Through the algorithm, distances (usually Euclidean distance or other distance metrics) between data points are calculated, and data points are gradually merged and clustered based on a principle of closest distance, thereby forming a hierarchical clustering tree. An average distance between all samples of two sample clusters is determined as an inter-cluster distance. A merging distance refers to a standard distance for selecting two clusters to be merged during the clustering process, which is actually the inter-cluster distance for determining which two clusters should be merged. Then, a suitable merging distance is determined by using an inflection point method.

A method for repairing lithography hotspots of a layout is provided according to the present disclosure. Specifically, when performing the method for repairing the lithography hotspots of the layout according to embodiments of the present disclosure, the following steps are implemented. First, a vector defect layout of an integrated circuit is acquired. Potential defects in circuit design are comprehensively captured by acquiring the vector defect layout containing lithography hotspots, such that problem regions in the circuit design can be accurately identified and necessary basic data can be provided for subsequent repair. Then, the vector defect layout is converted to a pixel image. A pixel defect layout conforming to a target format is obtained by converting the vector defect layout to the pixel image. This conversion process is adapted to the requirements of different lithography process formats, lays a foundation for subsequent image processing and repair, and effectively processes various types of layout data. Next, sliding window slicing processing is performed on the pixel defect layout. In this step, the pixel defect layout is partitioned into multiple layout slices through the sliding window slicing processing, thereby generating a first slice set. Each of the multiple layout slices represents a local region of the layout, which facilitates subsequent detailed defect identification and repair for the layout slices, and reduces processing complexity and refines an analysis on a defect region. On this basis, defect slices are identified based on a pre-constructed hotspot geometric template. In this step, the pre-constructed hotspot geometric template is used to quickly identify the defect slices. This template identification technology can effectively improve speed and accuracy of defect identification and avoid errors and delays caused by manual inspection. Finally, hotspot repair is performed based on a hotspot image repair rule. Specifically, based on the hotspot image repair rule and positions of the defect slices in the pixel defect layout, hotspot repair and vector conversion are performed on the pixel defect layout, so as to obtain a vector repaired layout. In this step, the hotspots generated in the lithography process can be effectively repaired, which ensures that the repaired layout conforms to design standards and production requirements, and significantly improves the quality and stability of the repair.

According to the present disclosure, by converting the vector defect layout to the pixel image, the sliding window slicing processing is performed on the pixel defect layout and the defect slices are automatically identified by using the hotspot geometric template, which avoids the inefficiency and instability of the conventional manual repair process. Further, the repair is performed based on the pre-constructed hotspot geometric template and the hotspot image repair rule, which can more accurately repair the lithography hotspots and reduce errors compared with the manual methods.

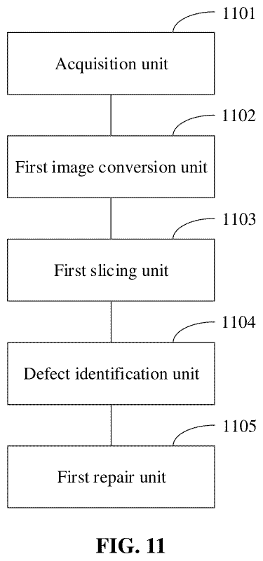

Reference is made to FIG. 11, which is a schematic structural diagram of an apparatus for repairing lithography hotspots of a layout according to an embodiment of the present disclosure. As shown in FIG. 11, the apparatus includes an acquisition unit 1101, a first image conversion unit 1102, a first slicing unit 1103, a defect identification unit 1104, and a first repair unit 1105.

The acquisition unit 1101 is configured to acquire a vector defect layout of an integrated circuit, where the vector defect layout includes mask patterns with lithography hotspots.

The first image conversion unit 1102 is configured to convert the vector defect layout to a pixel image to obtain a pixel defect layout conforming to a target format.

The first slicing unit 1103 is configured to perform sliding window slicing processing on the pixel defect layout to obtain a first slice set, where the first slice set includes multiple layout slices.

The defect identification unit 1104 is configured to identify defect slices in the first slice set based on a pre-constructed hotspot geometric template.

The first repair unit 1105 is configured to perform hotspot repair and conversion on the pixel defect layout based on a hotspot image repair rule and positions of the defect slices in the pixel defect layout, to obtain a vector repaired layout.

In a possible implementation, the first image conversion unit 1102 further includes an identification unit, a gridding unit, a mapping unit, a second image conversion unit, and a format conversion unit.

The identification unit is configured to identify shapes and vertex coordinates of polygons in the vector defect layout.

The gridding unit is configured to perform, based on the shapes and the vertex coordinates of the polygons in the vector defect layout, edge-based Hanan gridding on the vector defect layout to obtain a gridded layout, where the gridded layout includes multiple grids.

The mapping unit is configured to map the gridded layout to a pixel space to obtain a Boolean matrix and record horizontal spacings and vertical spacings between adjacent grids in the gridded layout.

The second image conversion unit is configured to convert the vector defect layout to an initial pixel layout based on the Boolean matrix in conjunction with the horizontal spacings and the vertical spacings between adjacent grids in the gridded layout.

The format conversion unit is configured to convert a format of the initial pixel layout to the target format to obtain the pixel defect layout.

In a possible implementation, the first slicing unit 1103 further includes a defining unit and a scanning unit.

The defining unit is configured to define a slicing window.

The scanning unit is configured for: the slicing window starting from a top left corner of the pixel defect layout and sliding successively from left to right and from top to bottom on the pixel defect layout by a predetermined step size until the pixel defect layout is entirely scanned, to obtain the first slice set.

A region covered by the slicing window during each scanning is a layout slice, and all layout slices compose the first slice set.

In a possible implementation, the first repair unit 1105 further includes a second repair unit, a replacement unit, and a vectorization unit.

The second repair unit is configured to perform hotspot repair on the defect slices based on the hotspot image repair rule to obtain multiple repaired slices.

The replacement unit is configured to replace, in the pixel defect layout, images at the positions of the defect slices one by one with their respective repaired slices in the multiple repaired slices, to obtain a pixel repaired layout.

The vectorization unit is configured to vectorize the pixel repaired layout to obtain the vector repaired layout.

In a possible implementation, the apparatus further includes a layout selection unit, a second slicing unit, a slice selection unit, and a merging and clustering unit.

The layout selection unit is configured to select X sample layouts, where each of the sample layouts includes multiple pixel-level mask patterns with lithography hotspots concentrated in a central region of the sample layout, and X is a positive integer.

The second slicing unit is configured to: for each of the sample layouts, perform sliding window slicing processing to obtain a second slice set corresponding to the sample layout, where the second slice set includes multiple sample slices.

The slice selection unit is configured to: for each of the sample layouts, select Y sample slices located around the central region of the sample layout to obtain Y target slices, where Y is a positive integer.

The merging and clustering unit is configured to merge and cluster X×Y target slices to obtain the hotspot geometric template.

In a possible implementation, the hotspot image repair rule includes a graphic movement rule and a graphic-edge shrinkage rule.

In a possible implementation, the apparatus further includes an evaluation unit and an execution unit.

The evaluation unit is configured to perform evaluation of a process window value on the pixel repaired layout.

The execution unit is configured to perform the process of vectorizing the pixel repaired layout to obtain the vector repaired layout in response to the evaluation passing.

Further, a device for repairing lithography hotspots of a layout is provided according to embodiments of the present disclosure. The device includes: a memory, a processor, and a computer program stored on the memory and executable on the processor, where the processor, when executing the computer program, implements the method for repairing the lithography hotspots of the layout as described above.

Moreover, a computer-readable storage medium is further provided according to an embodiment of the present disclosure. The computer-readable storage medium stores instructions. The instructions, when executed on a terminal device, cause the terminal device to perform the method for repairing the lithography hotspots of the layout as described above.

The apparatus for repairing the lithography hotspots of the layout is provided according to embodiments of the present disclosure. The acquisition unit 1101 is configured to acquire a vector defect layout of an integrated circuit. The first image conversion unit 1102 is configured to convert the vector defect layout to a pixel image to obtain a pixel defect layout conforming to a target format. The first slicing unit 1103 is configured to perform sliding window slicing processing on the pixel defect layout to obtain a first slice set, where the first slice set includes multiple layout slices. The defect identification unit 1104 is configured to identify defect slices in the first slice set based on a pre-constructed hotspot geometric template, so that the first repair unit 1105 performs hotspot repair and conversion on the pixel defect layout based on a hotspot image repair rule and positions of the defect slices in the pixel defect layout, to obtain a vector repaired layout. According to the present disclosure, by converting the vector defect layout to the pixel image, the sliding window slicing processing is performed on the pixel defect layout, achieving automated identification and repair of the lithography hotspots and significantly reducing manual intervention and workload. Moreover, based on the pre-constructed hotspot geometric template and the hotspot image repair rule, the defect regions can be quickly and accurately identified and repaired, thereby improving the repair efficiency and effect.

The above provides a detailed description of a method for repairing lithography hotspots of a layout and related devices according to the present disclosure. The embodiments in this specification are described in a progressive manner. Each of the embodiments is focused on describing its differences from other embodiments, and references may be made among these embodiments with respect to the same or similar parts. Since the apparatus disclosed in the embodiments corresponds to the method disclosed in the embodiments, the description for the apparatus is simple, and reference may be made to the description of the method for the relevant parts. It should be noted that, for those skilled in the art, several improvements and modifications may be made to the present disclosure without departing from the principle of the present disclosure, and these improvements and modifications also fall within the protection scope of the claims of the present disclosure.

It should be understood that in the present disclosure, the term “at least one” refers to a quantity equal to one or more, and the term “multiple” refers to a quantity equal to two or more. The term “and/or” are used to describe an association relationship between objects, and indicates three possible relationships. For example, “A and/or B” may indicate a case in which only A exists, a case in which only B exists, or a case in which both A and B exist. In the above cases, each of A and B may be singular or plural. The symbol “/” generally indicates that associated objects have an “or” relationship. The term “at least one of following” or similar expressions refer to any combination of following items, including any combination of a single item or multiple items. For example, at least one of a, b, or c may indicate: a, b, c, “a and b”, “a and c”, “b and c”, or “a, b, and c”, where each of a, b, and c may be singular or plural.

It should also be noted that in the present disclosure relational terms such as first and second are only for distinguishing one entity or operation from another without necessarily requiring or implying such actual relationship or order between these entities or operations. Furthermore, terms “include”, “comprise” or any other variants thereof are intended to be non-exclusive. Therefore, a process, method, article or device including a series of elements includes not only the elements but also other elements that are not enumerated or other elements inherent to such process, method, article or device. Unless expressively limited, the statement “including a . . . ” does not exclude the case that other identical elements may exist in the process, method, article or device including the series of elements.

1. A method for repairing lithography hotspots of a layout, comprising:
acquiring a vector defect layout of an integrated circuit, wherein the vector defect layout comprises N mask patterns with lithography hotspots and M mask patterns without lithography hotspots, and N is a positive integer and M is a non-negative integer;
converting the vector defect layout to a pixel image to obtain a pixel defect layout conforming to a target format;
performing sliding window slicing processing on the pixel defect layout to obtain a first slice set, wherein the first slice set comprises a plurality of layout slices;
identifying defect slices in the first slice set based on a pre-constructed hotspot geometric template; and
performing hotspot repair and conversion on the pixel defect layout based on a hotspot image repair rule and positions of the defect slices in the pixel defect layout, to obtain a vector repaired layout.

2. The method according to claim 1, wherein the converting the vector defect layout to a pixel image to obtain a pixel defect layout conforming to a target format comprises:
identifying shapes and vertex coordinates of polygons in the vector defect layout;
performing, based on the shapes and the vertex coordinates of the polygons in the vector defect layout, edge-based Hanan gridding on the vector defect layout to obtain a gridded layout, wherein the gridded layout comprises a plurality of grids;
mapping the gridded layout to a pixel space to obtain a Boolean matrix, and recording horizontal spacings and vertical spacings between adjacent grids in the gridded layout;
converting the vector defect layout to an initial pixel layout based on the Boolean matrix in conjunction with the horizontal spacings and the vertical spacings between adjacent grids in the gridded layout; and
converting a format of the initial pixel layout to the target format to obtain the pixel defect layout.

3. The method according to claim 1, wherein the performing sliding window slicing processing on the pixel defect layout to obtain a first slice set comprises:
defining a slicing window; and
the slicing window starting from a top left corner of the pixel defect layout and sliding successively from left to right and from top to bottom on the pixel defect layout by a predetermined step size until the pixel defect layout is entirely scanned, to obtain the first slice set,
wherein a region covered by the slicing window during each scanning is a layout slice, and all layout slices compose the first slice set.

4. The method according to claim 1, wherein the performing hotspot repair and conversion on the pixel defect layout based on a hotspot image repair rule and positions of the defect slices in the pixel defect layout, to obtain a vector repaired layout comprises:
performing hotspot repair on the defect slices based on the hotspot image repair rule to obtain a plurality of repaired slices;
replacing, in the pixel defect layout, images at the positions of the defect slices one by one with their respective repaired slices in the plurality of repaired slices, to obtain a pixel repaired layout; and
vectorizing the pixel repaired layout to obtain the vector repaired layout.

5. The method according to claim 1, wherein the hotspot geometric template is constructed by:
selecting X sample layouts, wherein each of the sample layouts comprises a plurality of pixel-level mask patterns with lithography hotspots concentrated in a central region of the sample layout, and X is a positive integer;
for each of the sample layouts, performing sliding window slicing processing to obtain a second slice set corresponding to the sample layout, wherein the second slice set comprises a plurality of sample slices;
for each of the sample layouts, selecting Y sample slices located around the central region of the sample layout to obtain Y target slices, wherein Y is a positive integer; and
merging and clustering XXY target slices to obtain the hotspot geometric template.

6. The method according to claim 1, wherein the hotspot image repair rule comprises a graphic movement rule and a graphic-edge shrinkage rule.

7. The method according to claim 4, wherein before the vectorizing the pixel repaired layout to obtain the vector repaired layout, the method further comprises:
performing evaluation of a process window value on the pixel repaired layout, and performing the process of vectorizing the pixel repaired layout to obtain the vector repaired layout in response to the evaluation passing.

8. A device for repairing lithography hotspots of a layout, comprising: a memory, a processor, and a computer program stored on the memory and executable on the processor, wherein the processor, when executing the computer program, performs:
acquiring a vector defect layout of an integrated circuit, wherein the vector defect layout comprises N mask patterns with lithography hotspots and M mask patterns without lithography hotspots, and N is a positive integer and M is a non-negative integer;
converting the vector defect layout to a pixel image to obtain a pixel defect layout conforming to a target format;
performing sliding window slicing processing on the pixel defect layout to obtain a first slice set, wherein the first slice set comprises a plurality of layout slices;
identifying defect slices in the first slice set based on a pre-constructed hotspot geometric template; and
performing hotspot repair and conversion on the pixel defect layout based on a hotspot image repair rule and positions of the defect slices in the pixel defect layout, to obtain a vector repaired layout.

9. The device according to claim 8, wherein the converting the vector defect layout to a pixel image to obtain a pixel defect layout conforming to a target format comprises:
identifying shapes and vertex coordinates of polygons in the vector defect layout;
performing, based on the shapes and the vertex coordinates of the polygons in the vector defect layout, edge-based Hanan gridding on the vector defect layout to obtain a gridded layout, wherein the gridded layout comprises a plurality of grids;
mapping the gridded layout to a pixel space to obtain a Boolean matrix, and recording horizontal spacings and vertical spacings between adjacent grids in the gridded layout;
converting the vector defect layout to an initial pixel layout based on the Boolean matrix in conjunction with the horizontal spacings and the vertical spacings between adjacent grids in the gridded layout; and
converting a format of the initial pixel layout to the target format to obtain the pixel defect layout.

10. The device according to claim 8, wherein the performing sliding window slicing processing on the pixel defect layout to obtain a first slice set comprises:
defining a slicing window; and
the slicing window starting from a top left corner of the pixel defect layout and sliding successively from left to right and from top to bottom on the pixel defect layout by a predetermined step size until the pixel defect layout is entirely scanned, to obtain the first slice set,
wherein a region covered by the slicing window during each scanning is a layout slice, and all layout slices compose the first slice set.

11. The device according to claim 8, wherein the performing hotspot repair and conversion on the pixel defect layout based on a hotspot image repair rule and positions of the defect slices in the pixel defect layout, to obtain a vector repaired layout comprises:
performing hotspot repair on the defect slices based on the hotspot image repair rule to obtain a plurality of repaired slices;
replacing, in the pixel defect layout, images at the positions of the defect slices one by one with their respective repaired slices in the plurality of repaired slices, to obtain a pixel repaired layout; and
vectorizing the pixel repaired layout to obtain the vector repaired layout.

12. The device according to claim 8, wherein the hotspot geometric template is constructed by:
selecting X sample layouts, wherein each of the sample layouts comprises a plurality of pixel-level mask patterns with lithography hotspots concentrated in a central region of the sample layout, and X is a positive integer;
for each of the sample layouts, performing sliding window slicing processing to obtain a second slice set corresponding to the sample layout, wherein the second slice set comprises a plurality of sample slices;
for each of the sample layouts, selecting Y sample slices located around the central region of the sample layout to obtain Y target slices, wherein Y is a positive integer; and
merging and clustering XXY target slices to obtain the hotspot geometric template.

13. The device according to claim 8, wherein the hotspot image repair rule comprises a graphic movement rule and a graphic-edge shrinkage rule.

14. The device according to claim 11, wherein before the vectorizing the pixel repaired layout to obtain the vector repaired layout, the device is further configured for:
performing evaluation of a process window value on the pixel repaired layout, and performing the process of vectorizing the pixel repaired layout to obtain the vector repaired layout in response to the evaluation passing.

15. A computer-readable storage medium storing instructions, wherein the instructions, when being executed on a terminal device, cause the terminal device to perform:
acquiring a vector defect layout of an integrated circuit, wherein the vector defect layout comprises N mask patterns with lithography hotspots and M mask patterns without lithography hotspots, and N is a positive integer and M is a non-negative integer;
converting the vector defect layout to a pixel image to obtain a pixel defect layout conforming to a target format;
performing sliding window slicing processing on the pixel defect layout to obtain a first slice set, wherein the first slice set comprises a plurality of layout slices;
identifying defect slices in the first slice set based on a pre-constructed hotspot geometric template; and
performing hotspot repair and conversion on the pixel defect layout based on a hotspot image repair rule and positions of the defect slices in the pixel defect layout, to obtain a vector repaired layout.
